(19) United States
(12) Patent Application Publication
(10) Pub. No.: US 2024/0153894 A1
(43) Pub. Date: May 9, 2024

(54) STRUCTURE FOR THERMAL MANAGEMENT IN HYBRID BONDING

(71) Applicant: INTERNATIONAL BUSINESS MACHINES CORPORATION, ARMONK, NY (US)

(72) Inventors: John Knickerbocker, Monroe, NY (US); Mukta Ghate Farooq, HOPEWELL JUNCTION, NY (US); Keiji Matsumoto, Yokohama (JP)

(21) Appl. No.: 18/053,774

(22) Filed: Nov. 9, 2022

(51) Int. Cl. H01L 23/00; H01L 25/065

(52) U.S. Cl. CPC H01L 24/05; H01L 24/08; H01L 24/80; H01L 25/0657; H01L 2224/0231; H01L 2224/02372; H01L 2224/05548; H01L 2224/05554; H01L 2224/05555; H01L 2224/05576; H01L 2224/05647; H01L 2224/05687; H01L 2224/08055; H01L 2224/08056; H01L 2224/08145; H01L 2224/80203; H01L 2224/80895; H01L 2224/80896; H01L 2225/06524; H01L 2225/06527; H01L 2225/06541; H01L 2225/06589; H01L 2924/351

(57) ABSTRACT

Embodiments of present invention provide a semiconductor structure. The semiconductor structure includes a first semiconductor wafer and a second semiconductor wafer; and a bonding structure between the first semiconductor wafer and the second semiconductor wafer, where the bonding structure includes a first coaxial pad embedded in a first dielectric layer and a second coaxial pad embedded in a second dielectric layer, and the first coaxial pad is substantially aligned with the second coaxial pad. In one embodiment, the first coaxial pad includes an inner pad of substantially rectangular shape and an outer pad of substantially rectangular ring shape surrounding the inner pad.

### BACKGROUND

The present application relates to manufacturing of semiconductor integrated circuits. More particularly, it relates to semiconductor structures with improving thermal management in hybrid bonding of semiconductor wafers.

With the continued scaling of semiconductor integrated circuits, three-dimensional (3D) integration remains one of the viable options for further increasing the device density in a given device footprint. For example, wafer bonding is one of the approaches that achieves the above purpose by stacking one semiconductor wafer on top of another one thereby doubling, tripling, or even quadrupling the density of devices.

Hybrid bonding is one of the most promising bonding candidates for fine pitch interconnect such as for those below 10 micrometer pitches. In a hybrid bonding scheme, both metal bonding and dielectric bonding are simultaneously used. Generally, silicon-oxide (SiO2) is used as the dielectric material used in the dielectric bonding. However, thermal conductivity of SiO2 is known to be low, for example around 1.3 W/mK. The low conductivity of SiO2 does not help or contribute to thermal management of the bonded device structure. On the other hand, copper (Cu) is generally used in the metal bonding which has a high thermal conductivity such as around 398 W/mK.

### SUMMARY

Embodiments of present invention provide a semiconductor structure. The semiconductor structure includes a first semiconductor wafer and a second semiconductor wafer; and a bonding structure between the first semiconductor wafer and the second semiconductor wafer, where the bonding structure includes a first coaxial pad embedded in a first dielectric layer and a second coaxial pad embedded in a second dielectric layer, and the first coaxial pad is substantially aligned with the second coaxial pad.

In one embodiment, the first coaxial pad includes a first inner pad and a first outer pad, the first inner pad has a substantially circular shape, and the first outer pad has a substantially rectangular ring shape surrounding the first inner pad to have different distances to the first inner pad along a periphery of the first outer pad.

In another embodiment, the first coaxial pad includes a first inner pad and a first outer pad, the first inner pad has a substantially rectangular shape, and the first outer pad has a substantially rectangular ring shape surrounding the first inner pad to have a substantially same distance to the first inner pad along a periphery of the first outer pad.

In one embodiment, the first coaxial pad includes a first inner pad and a first outer pad, and wherein the first dielectric layer is a silicon-oxide (SiO2) layer surrounding the first coaxial pad and in-between the first inner pad and the first outer pad.

In another embodiment, the first coaxial pad and the second coaxial pad have substantially same shapes and are made of copper (Cu).

In one embodiment, the first semiconductor wafer at a frontside thereof includes a back-end-of-line (BEOL) structure and the second semiconductor wafer at a backside thereof includes a redistribution layer (RDL), and wherein the bonding structure bonds the BEOL structure of the first semiconductor wafer directly with the RDL of the second semiconductor wafer.

In another embodiment, the first semiconductor wafer at a frontside thereof includes a first back-end-of-line (BEOL) structure and the second semiconductor wafer at a frontside thereof includes a second BEOL structure, and wherein the bonding structure bonds the first BEOL structure of the first semiconductor wafer directly with the second BEOL structure of the second semiconductor wafer.

Embodiments of present invention provide a method of forming a semiconductor structure. The method includes forming a first semiconductor chip; forming a first dielectric layer on the first semiconductor chip, the first dielectric layer having at least a first coaxial pad embedded therein; forming a second semiconductor chip; forming a second dielectric layer on the second semiconductor chip, the second dielectric layer having at least a second coaxial pad embedded therein; and bonding the first dielectric layer with the second dielectric layer and causing the first coaxial pad in the first dielectric layer to be substantially aligned with the second coaxial pad in the second dielectric layer.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of cross-sectional view of a semiconductor structure with multiple semiconductor wafers being stacked together through bonding according to one embodiment of present invention;

FIGS. 2A, 2B, and 2C are demonstrative illustrations of a bonding structure in a semiconductor structure with bonded semiconductor wafers according to one embodiment of present invention;

FIGS. 3A, 3B, and 3C are demonstrative illustrations of a bonding structure in a semiconductor structure with bonded semiconductor wafers according to another embodiment of present invention; and

FIG. 4 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

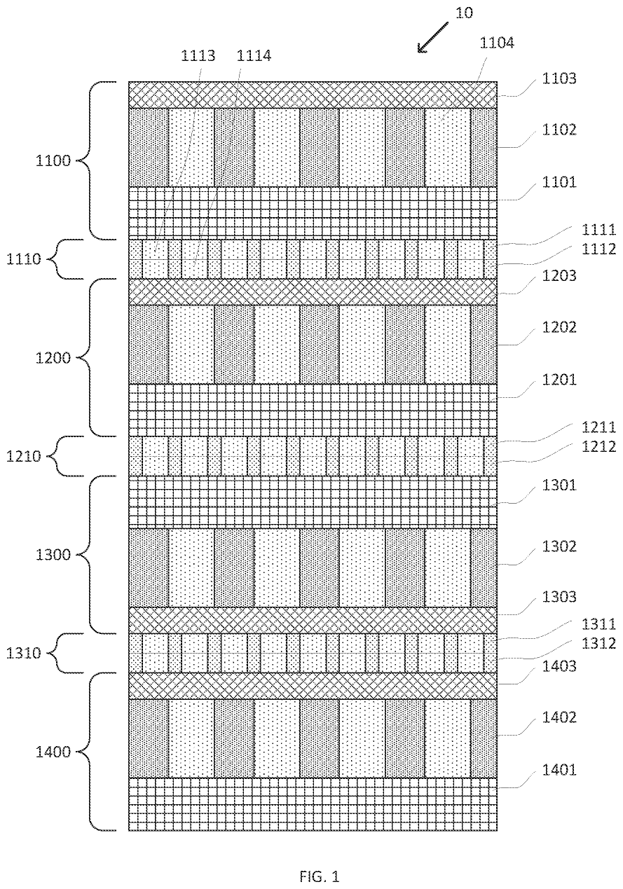

FIG. 1 is a demonstrative illustration of cross-sectional view of a semiconductor structure according to embodiments of present invention. More specifically, FIG. 1 demonstratively illustrates a semiconductor structure 10 with multiple semiconductor wafers being stacked together through bonding. The semiconductor structure 10 may include a first semiconductor wafer 1100 being stacked on top of a second semiconductor wafer 1200. The second semiconductor wafer 1200 is in-turn stacked on top of a third semiconductor wafer 1300. The third semiconductor wafer 1300 is in-turn stacked on top of a fourth semiconductor wafer 1400. However, embodiments of present invention are not limited in this aspect. For example, more or fewer number of semiconductor wafers, such as two or three semiconductor wafers or more than four semiconductor wafers, may be stacked together. In one embodiment, the various semiconductor wafers may be various semiconductor chips. For example, the first semiconductor wafer 1100 may be a first semiconductor chip; the second semiconductor wafer 1200 may be a second semiconductor chip; the third semiconductor wafer 1300 may be a third semiconductor chip; and the fourth semiconductor wafer 1400 may be a fourth semiconductor chip.

Each semiconductor wafer may include a substrate, a front-end-of-line (FEOL) structure and a back-end-of-line (BEOL) structure on a frontside of the wafer, and a redistribution layer (RDL) on a backside of the wafer. For example, the semiconductor wafer 1100 (shown upside-down in FIG. 1) may include a substrate 1102 with one or more through-silicon-vias 1104 (TSVs) formed therein, a FEOL structure (not shown) above the semiconductor substrate 1102 and a BEOL structure 1101 on top of the FEOL structure at a frontside of the semiconductor wafer 1100. At a backside of the semiconductor wafer 1100, there may be formed a redistribution layer (RDL) 1103.

Similarly, the semiconductor wafer 1200 (shown upside-down in FIG. 1) may include a substrate 1202, a FEOL structure (not shown) above the semiconductor substrate 1202 and a BEOL structure 1201 on top of the FEOL structure at a frontside of the semiconductor wafer 1200. At a backside of the semiconductor wafer 1200, there may be formed a redistribution layer (RDL) 1203. The semiconductor wafer 1300 may include a substrate 1302, a FEOL structure (not shown) above the semiconductor substrate 1302 and a BEOL structure 1301 on top of the FEOL structure at a frontside of the semiconductor wafer 1300. At a backside of the semiconductor wafer 1300, there may be formed a redistribution layer (RDL) 1303. The semiconductor wafer 1400 (shown upside-down in FIG. 1) may include a substrate 1402, a FEOL structure (not shown) above the semiconductor substrate 1402 and a BEOL structure 1401 on top of the FEOL structure at a frontside of the semiconductor wafer 1400. At a backside of the semiconductor wafer 1400, there may be formed a redistribution layer (RDL) 1403.

The semiconductor wafers 1100, 1200, 1300, and 1400 may be stacked together through bonding such as, for example, through a thermal compression bonding or a hybrid bonding process. Further, in stacking the semiconductor wafers 1100 and 1200 together, embodiments of present invention provide using a bonding structure 1110 that includes a first dielectric layer 1111 and a second dielectric layer 1112. In one embodiment, the first dielectric layer 1111 and the second dielectric layer 1112 may be silicon-oxide (SiO2).

The first dielectric layer 1111 may have one or more coaxial pads such as a first coaxial pad 1113 embedded therein and the second dielectric layer 1112 may have one or more coaxial pads such as a second coaxial pad 1114 embedded therein. In one embodiment, the one or more coaxial pads such as the first coaxial pad 1113 and the second coaxial pad 1114 may be copper (Cu). In one embodiment, the first coaxial pad 1113 and the second coaxial pad may have a substantially same shape and the first coaxial pad 1113 may be substantially aligned with the second coaxial pad 1114. The first semiconductor wafer 1100 may be bonded with the second semiconductor wafer 1200 front-to-back. In other words, the first dielectric layer 1111 may be formed on top of the BEOL structure at the frontside of the first semiconductor wafer 1100 and the second dielectric layer 1112 may be formed on top of the RDL 1203 at the backside of the second semiconductor wafer 1200 and the frontside of the semiconductor wafer 1100 is bonded to the backside of the semiconductor wafer 1200.

However, embodiments of present invention are not limited in this aspect. For example, the semiconductor wafer 1200 may be bonded to the semiconductor wafer 1300 front-to-front. In other words, the BEOL structure 1201 at the frontside of the semiconductor wafer 1200 may be bonded to the BEOL structure 1301 at the frontside of the semiconductor wafer 1300 and by using a bonding structure 1210 that includes a first dielectric layer 1211 and a second dielectric layer 1212. Further for example, the semiconductor wafer 1300 may be bonded to the semiconductor wafer 1400 back-to-back. In other words, the RDL 1303 at the backside of the semiconductor wafer 1300 may be bonded to the RDL 1403 at the backside of the semiconductor wafer 1400 and by using a bonding structure 1310 that includes a first dielectric layer 1311 and a second dielectric layer 1312.

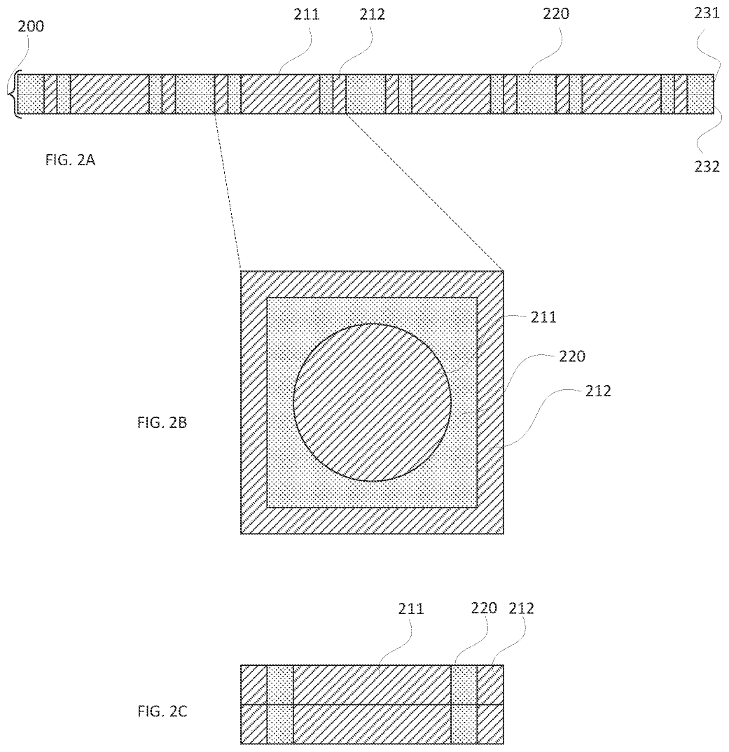

FIGS. 2A, 2B, and 2C are demonstrative illustrations of a bonding structure in a semiconductor structure with bonded semiconductor wafers according to one embodiment of present invention. More specifically, FIG. 2A is a demonstrative illustration of cross-sectional view of a bonding structure, such as the bonding structure 1110, 1210, 1310, and 1410 in FIG. 1, that includes a first dielectric layer 231 and a second dielectric layer 232 that are bonded together. The semiconductor wafers or chips that are attached to the top of the first dielectric layer 231 (such as 1100, 1200, and 1300) and to the bottom of the second dielectric layer 232 (such as 1200, 1300, and 1400, respectively) are not shown in FIG. 2A. The first dielectric layer 231, and similarly the second dielectric layer 232, includes one or more, or at least one, pad structures such as a first pad structure 211/212 that is embedded in the dielectric material 220 of the first dielectric layer 231. In one embodiment, the first pad structure 211/212 may be a first coaxial pad 211/212 that has the resemblance to a coaxial cable. Similarly, the second dielectric layer 232 may include one or more pad structures, such as, a second pad structure or a second coaxial pad.

FIG. 2B is a top view of the coaxial pad 211/212. More specifically, the first coaxial pad 211/212 may include a first inner pad 211 and a first outer pad 212. The first inner pad 211 may be in a substantially circular shape and the first outer pad 212 may be in a substantially rectangular ring shape surrounding the first inner pad 211. For example, the first outer pad 212 may be in a substantially square ring shape. The first inner pad 211 may be separated from the first outer pad 212 by the dielectric material 220 of the first dielectric layer 231. In other words, the dielectric material 220 may fill in-between the first inner pad 211 and the first outer pad 212. Since the first inner pad 211 and the first outer pad 212 have different shapes, the first outer pad 212 may have different distances, such as S1 and S2, to the first inner pad 211 along a periphery of the first outer pad 211. Similar to the first coaxial pad 211/212 of the first dielectric layer 231, the second coaxial pad of the second dielectric layer 232 may have a substantially same shape as that of the first coaxial pad 211/212 of the first dielectric layer 231.

FIG. 2C is a demonstrative illustration of cross-sectional view of the first coaxial pad showing the first inner pad 211, the first outer pad 212 and the dielectric material 220 in-between the first inner pad 211 and the first outer pad 212.

According to embodiments of present invention, and a person skilled in the art will appreciate that as well, the use of a coaxial pad not only increases the overall contact areas of the conductive material (by the amount of the first outer pad 212), which helps improve the overall thermal conductivity of the bonding structure. For example, the coaxial pad is made of copper that has a thermal conductivity value of around 398 W/mK, which is much higher than that of the surrounding dielectric material of SiO2, which has a thermal conductivity of around 1.3 W/mK. The use of a pad structure in a coaxial form or shape also helps the passage of electrical signals over a certain signal frequency range, in addition to passing electric power for power consumption only as in a conventional pad structure.

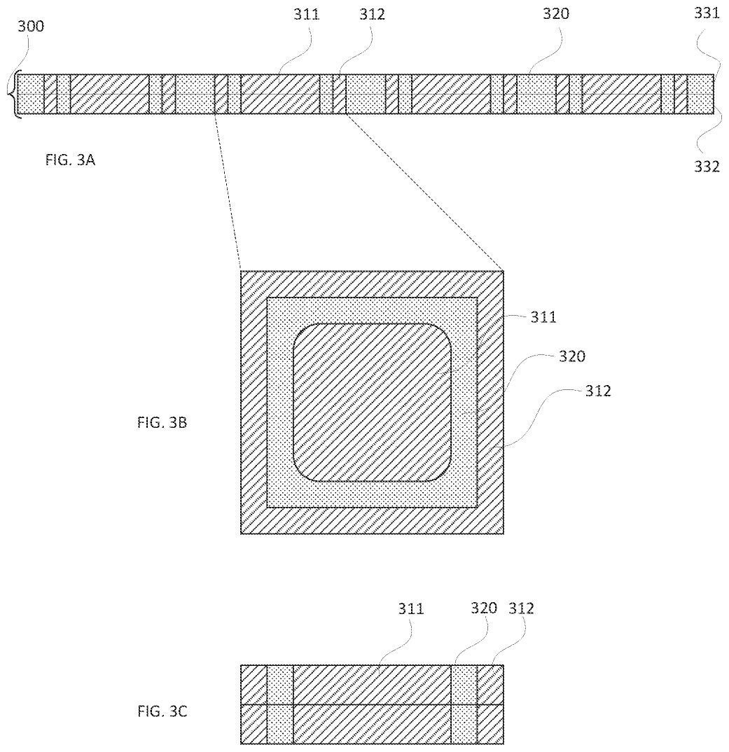

FIGS. 3A, 3B, and 3C are demonstrative illustrations of a bonding structure in a semiconductor structure with bonded semiconductor wafers according to another embodiment of present invention. More specifically, FIG. 3A is a demonstrative illustration of cross-sectional view of a bonding structure that includes a first dielectric layer 331 and a second dielectric layer 332 that are bonded together. The first dielectric layer 331, and similarly the second dielectric layer 332, includes one or more, or at least one, pad structures such as a first pad structure 311/312 that is embedded in the dielectric material 320 of the first dielectric layer 331. In one embodiment, the first pad structure 311/312 may be a first coaxial pad 311/312 that has the resemblance to a coaxial cable. Similarly, the second dielectric layer 332 may include one or more pad structures, such as, a second pad structure or a second coaxial pad.

FIG. 3B is a top view of the coaxial pad 311/312. More specifically, the first coaxial pad 311/312 may include a first inner pad 311 and a first outer pad 312. The first inner pad 311 may be in a substantially rectangular shape, such as a substantially square shape, and the first outer pad 312 may be in a substantially rectangular ring shape surrounding the first inner pad 311. For example, the first outer pad 312 may be in a substantially square ring shape as well. The first inner pad 311 may be separated from the first outer pad 312 by the dielectric material 320 of the first dielectric layer 331. In other words, the dielectric material 320 may fill in-between the first inner pad 311 and the first outer pad 312. In one embodiment, the first inner pad 311 and the first outer pad 312 have substantially similar shapes, such as rectangular shapes or square shapes but different in sizes, the first outer pad 312 may have a substantially same distance S1 to the first inner pad 311 along a periphery of the first outer pad 311. Similar to the first coaxial pad 311/312 of the first dielectric layer 331, the second coaxial pad of the second dielectric layer 332 may have a substantially same shape as that of the first coaxial pad 311/312 of the first dielectric layer 331.

FIG. 3C is a demonstrative illustration of cross-sectional view of the first coaxial pad showing the first inner pad 311, the first outer pad 312 and the dielectric material 320 in-between the first inner pad 311 and the first outer pad 312.

According to embodiments of present invention, the use of an inner pad that is substantially rectangular in shape further increases the contact area of the conductive material of copper, as comparing to the inner pad of a circular shape. The increase in contact area helps improve the overall thermal conductivity of the bonding structure, in addition to the electric signal passing functionality provided by the coaxial shape of the pad structure.

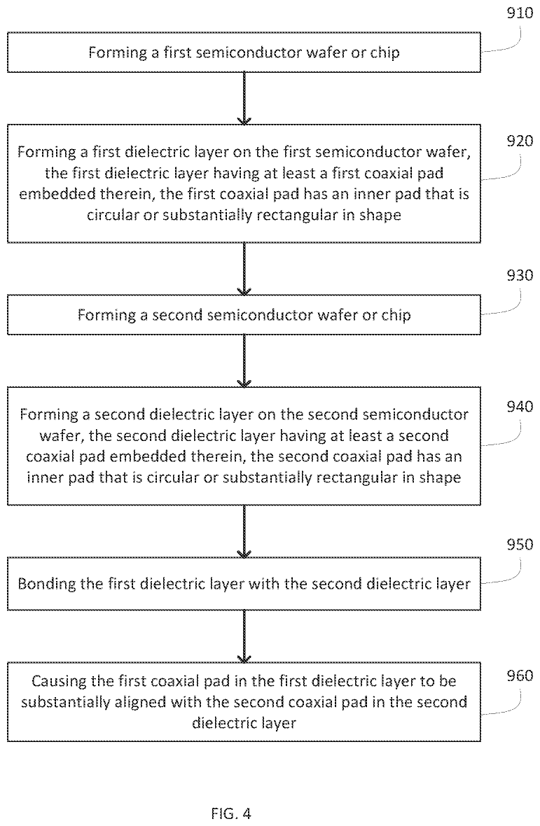

FIG. 4 is a demonstrative illustration of a flow-chart of a method of manufacturing a semiconductor structure according to embodiments of present invention. The method includes (910) forming a first semiconductor wafer (or chip) that has a frontside and a backside, the frontside includes a first back-end-of-line (BEOL) structure and the backside includes a first redistribution layer (RDL); (920) forming a first dielectric layer on the first semiconductor wafer (or chip), the first dielectric layer has at least a first coaxial pad embedded therein, and the first coaxial pad has an inner pad that is circular or substantially rectangular in shape; (930) forming a second semiconductor wafer (or chip) that has a frontside and a backside, the frontside includes a second BEOL structure and the backside includes a second RDL; (940) forming a second dielectric layer on the second semiconductor wafer, the second dielectric layer has at least a second coaxial pad embedded therein, and the second coaxial pad has an inner pad that is circular or substantially rectangular in shape; (950) bonding the first dielectric layer with the second dielectric layer; and (960) causing the first coaxial pad in the first dielectric layer to be substantially aligned with the second coaxial pad in the second dielectric layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first semiconductor wafer and a second semiconductor wafer; and
a bonding structure between the first semiconductor wafer and the second semiconductor wafer,
where the bonding structure comprises a first coaxial pad embedded in a first dielectric layer and a second coaxial pad embedded in a second dielectric layer, and the first coaxial pad is substantially aligned with the second coaxial pad.

2. The semiconductor structure of claim 1, wherein the first coaxial pad includes a first inner pad and a first outer pad, the first inner pad has a substantially circular shape, and the first outer pad has a substantially rectangular ring shape surrounding the first inner pad to have different distances to the first inner pad along a periphery of the first outer pad.

3. The semiconductor structure of claim 1, wherein the first coaxial pad includes a first inner pad and a first outer pad, the first inner pad has a substantially rectangular shape, and the first outer pad has a substantially rectangular ring shape surrounding the first inner pad to have a substantially same distance to the first inner pad along a periphery of the first outer pad.

4. The semiconductor structure of claim 1, wherein the first coaxial pad includes a first inner pad and a first outer pad, and wherein the first dielectric layer is a silicon-oxide (SiO2) layer surrounding the first coaxial pad and in-between the first inner pad and the first outer pad.

5. The semiconductor structure of claim 1, wherein the first coaxial pad and the second coaxial pad have substantially same shapes and are made of copper (Cu).

6. The semiconductor structure of claim 1, wherein the first semiconductor wafer at a frontside thereof includes a back-end-of-line (BEOL) structure and the second semiconductor wafer at a backside thereof includes a redistribution layer (RDL), and wherein the bonding structure bonds the BEOL structure of the first semiconductor wafer directly with the RDL of the second semiconductor wafer.

7. The semiconductor structure of claim 1, wherein the first semiconductor wafer at a frontside thereof includes a first back-end-of-line (BEOL) structure and the second semiconductor wafer at a frontside thereof includes a second BEOL structure, and wherein the bonding structure bonds the first BEOL structure of the first semiconductor wafer directly with the second BEOL structure of the second semiconductor wafer.

8. A semiconductor structure comprising:
a first semiconductor chip having a first back-end-of-line (BEOL) structure;
a second semiconductor chip having a frontside with a second BEOL structure and a backside with a redistribution layer (RDL); and
a bonding structure between the first semiconductor chip and the second semiconductor chip,
where the bonding structure comprises a first dielectric layer with at least a first pad structure embedded therein and a second dielectric layer with at least a second pad structure embedded therein, wherein the first pad structure includes a first inner pad and a first outer pad, and wherein the first pad structure is substantially aligned with the second pad structure.

9. The semiconductor structure of claim 8, wherein the first inner pad has a substantially circular shape, and the first outer pad has a substantially rectangular ring shape surrounding the first inner pad.

10. The semiconductor structure of claim 8, wherein the first inner pad has a substantially rectangular shape, and the first outer pad has a substantially rectangular ring shape surrounding the first inner pad.

11. The semiconductor structure of claim 10, wherein the first dielectric layer is a silicon-oxide (SiO2) layer surrounding the first pad structure and in-between the first inner pad and the first outer pad.

12. The semiconductor structure of claim 8, wherein the first pad structure in the first dielectric layer and the second pad structure in the second dielectric layer have substantially same shapes and are made of copper (Cu).

13. The semiconductor structure of claim 8, wherein the bonding structure bonds the first BEOL structure of the first semiconductor chip directly with the RDL of the second semiconductor chip at the backside thereof.

14. The semiconductor structure of claim 8, wherein the bonding structure bonds the first BEOL structure of the first semiconductor chip directly with the second BEOL structure of the second semiconductor chip at the frontside thereof.

15. A method comprising:
forming a first semiconductor chip;
forming a first dielectric layer on the first semiconductor chip, the first dielectric layer having at least a first coaxial pad embedded therein;
forming a second semiconductor chip;
forming a second dielectric layer on the second semiconductor chip, the second dielectric layer having at least a second coaxial pad embedded therein; and
bonding the first dielectric layer with the second dielectric layer and causing the first coaxial pad in the first dielectric layer to be substantially aligned with the second coaxial pad in the second dielectric layer.

16. The method of claim 15, wherein the first semiconductor chip includes a first back-end-of-line (BEOL) structure and the second semiconductor chip, at a frontside thereof, includes a second BEOL structure and, at a backside thereof, includes a redistribution layer (RDL), wherein forming the first dielectric layer includes forming the first dielectric layer directly on top of the first BEOL structure and forming the second dielectric layer includes forming the second dielectric layer directly on top of the second BEOL structure at the frontside of the second semiconductor chip.

17. The method of claim 15, wherein the first semiconductor chip includes a back-end-of-line (BEOL) structure and the second semiconductor chip, at a frontside thereof, includes a second BEOL structure and, at a backside thereof, includes a redistribution layer (RDL), wherein forming the first dielectric layer includes forming the first dielectric layer directly on top of the first BEOL structure and forming the second dielectric layer includes forming the second dielectric layer directly on top of the RDL at the backside of the second semiconductor chip.

18. The method of claim 15, wherein the first coaxial pad includes a first inner pad and a first outer pad, the first inner pad has a substantially circular shape, and the first outer pad has a substantially rectangular ring shape surrounding the first inner pad.

19. The method of claim 15, wherein the first coaxial pad includes a first inner pad and a first outer pad, the first inner pad has a substantially rectangular shape, and the first outer pad has a substantially rectangular ring shape surrounding the first inner pad.

20. The method of claim 15, wherein the first and second coaxial pads are made of copper (Cu) and the first and second dielectric layers are silicon-oxide (SiO2) layers.
